(19) United States
(12) Patent Application Publication
(10) Pub. No.: US 2008/0116588 A1
(43) Pub. Date: May 22, 2008

(54) Assembly and Method of Placing the Assembly on an External Board

(75) Inventors: Marcus H. Van Kleef, Nijmegen (NL); Rene W. J. M. Van Den Boomem, Asten (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/632,609

(22) PCT Filed: Jul. 12, 2005
(86) PCT No.: PCT/IB05/52310

§ 371 Date: Dec. 7, 2007

(30) Foreign Application Priority Data
Jul. 13, 2004 (EP) 04103314.3

(51) Int. Cl. H01L 23/498; H05K 3/34; H01L 21/60

(52) U.S. Cl. 257/779; 257/E23.06

(57) ABSTRACT

The assembly comprises an electronic device (20) that is attached to a first side (11) of a carrier substrate (10) with solder connections (18). The first side (11) of the substrate (10) is provided with bond pads (15) and a solder resist layer (16). The space between the substrate (10) and the electronic device (20) is filled with an encapsulant (19) The substrate (10) further comprises contact pads for connection to an external board. The solder resist layer (16) is patterned according to a pattern that includes an aperture (161) adjacent to a first bond pad (15). This aperture (161) is ring-shaped and forms the circumference of the first bond pad. Herewith, delamination is prevented, also if a via (142) is present in the substrate (10) below the bond pad (15).

The invention relates to an assembly comprising an electronic device that is attached to a first side of a carrier substrate with a solder connection, said first side of the substrate being provided with bond pads and a solder resist layer, any space between the substrate and the electronic device being filled with an encapsulant, the substrate further comprising contact pads for connection to an external board.

The invention also relates to a method of placing an assembly onto an external board with a reflow soldering process.

Such an assembly is known for instance from US-A 2003/0116863. The known assembly comprises a semiconductor chip mounted on a carrier substrate. The carrier substrate is formed of a glass epoxy resin. Bumps are used as the solder connection. It is formed of gold of 75 microns in diameter and 45 μm in height. The solder resist layer is present at a distance from an end face of the semiconductor chip on the first side of the carrier substrate. The distance is conventionally 200 μm.

Warping is found to occur in the carrier substrate. This is due to the fact that the glass transition temperature of the carrier substrate is lower than the temperature at which the bonding material of the solder connection or encapsulant is dried/set. Furthermore, the setting of the encapsulant needs a heat treatment at elevated temperature, which though not surpassing the limits of the carrier substrate, does result in warping as well. As a consequence, undesired delamination of chip and carrier substrate may take place, particularly at the interface between encapsulant and solder resist layer. This problem is solved in the prior art document by the provision of additional solder connections that are connected to non-operating electrodes at the semiconductor chip and that do not have any electrical function.

Although the prior art solution will work, it is an expensive solution to prevent the delamination.

It is therefore an object of the present invention to provide an assembly of the kind mentioned in the opening paragraph, in which the delamination is prevented in a more cost-effective manner.

This object is achieved in that the solder resist layer is patterned according to a pattern that includes an aperture adjacent to a first bond pad, which aperture is ring-shaped and forms the circumference of the first bond pad.

Surprisingly it was found that such a circumferential aperture leads to prevention of detrimental delamination of the substrate and the electronic device during test or after placement of the assembly onto an external board. This effect is explained by measurements showing that the delamination occurs at the interface of solder resist and the encapsulant. Near the melting temperature of the bump of the solder material the delamination propagates and can lead to malfunctioning and fracture or shorting of the electrical connection between the electronic device and the carrier substrate. The trench thus limits the propagation of the delamination, and prevents outflow of the bump.

It is an advantage of the assembly of the invention that it has a better result in an MSL-test. An MSL test is a test for the Moisture Sensitivity Level, that has been prescribed in standards of the JEDEC Standardization body. Packages of electronic components need to be tested in an MSL-test. In this test, the package is put in a conditioned room with predefined temperature and moisture for a specific period of time. The package will then take up moisture. Hereafter, the package is led through a reflow process including a heat treatment at a certain temperature. This has the result that the moisture will have the tendency to leave the package with a substantial force. The lower the MSL level, the better the moisture resistance and the less critical the processing needs to be during attachment of the assembly to an external board.

Particularly useful is the invention in case the first bond pad is located on top of a vertical interconnect. Solder connections on such first bond pads have turned out to be very sensitive to delamination. This seems due to the local interruption of the substrate, allowing a point of easy delamination and a point at which stresses are built up. Furthermore, such a vertical interconnect is a good electrical and thermal connection.

It is observed that the aperture does not need to be the circumference of only one bond pad. It may well be that it forms the circumference of a couple of bond pad structures, and has a corresponding shape. This reduces the area and has turned out to work adequately. A circumference of two bond pad structures by a single aperture following the contours of both bond pad structures has found to work successfully.

In a further embodiment, the substrate is a substrate of an electrically insulating material with internal conductors. Such a substrate is generally called a multilayer substrate. The electrically insulating material may be ceramic but also an organic material filled with an adequate filler compound. Moreover, the substrate may contain specific functionality such as capacitor and inductor structures. For this purpose, also specific dielectric and/or magnetic materials may be added to the substrate. The measure is particularly suitable for a substrate of organic material in view of the substantial coefficient of thermal expansion of such substrates. Alternatively, however, the substrate may be a semiconductor substrate. The carrier substrate is preferably provided with contact pads for external connection. These may be present on either the first or the second side of the carrier substrate, in the form of a ball grid array, a land grid array, or U-shaped side contacts.

It is preferred that after provision of the encapsulant the complete assembly is provided with an encapsulation in the form of a moulding compound. The encapsulant is particularly a material known as underfill in the art, and composed of the class of epoxies, polyimides, acrylates and the like. Instead of the encapsulation in the form of a moulding compound metal caps can be used as well as glass layers.

The solder connection between the electronic device and the substrate may be any type of solder or metal. Lead free solder is preferred for environmental reasons. The solder connection is preferably a bump.

The contact pads for connection to an External board may be end contacts, solder balls in the form of a ball grid array, but also contacts in the form of a land grid array.

The electronic device is suitably a semiconductor device, and a semiconductor device used for high-frequency and/or power applications, in which the electrical and/or thermal grounding is of utmost importance. However, it could as well be a passive component, or a similar component, such as a BAW or SAW filter or a MEMS device.

It is preferred that the assembly comprises a second electronic device that is attached to the first side of the carrier substrate, the—first—and second electronic device being mutually interconnected via interconnects at and/or in the carrier substrate. The assembly thus constitutes a subsystem that may fulfill a function. Examples of subsystems can be found for RF applications, such as a front-end module including a power amplifier, an antenna switch and matching circuit as well as further additional passive components for one or more frequency bands. The second electronic device may be a semiconductor device, but is alternatively a passive component, a sensor, a network of passive components, a filter or the like. The second electronic device may be placed on the substrate with bumps, but also as standard SMD-components provided with end contacts.

As will be understood, it is suitable that there is more than one bond pad, and that each bond pad is provided with a circumferential aperture. With two neighboring bond pads, the circumferential apertures in the solder resist may fuse. That is to say: there is an area between the first and the second bond pad wherein the solder resist layer is completely absent.

The invention further relates to the use of the assembly of the invention for placement on an external board.

These and other aspects of the assembly of the invention will be further explained with reference to the figures, in which:

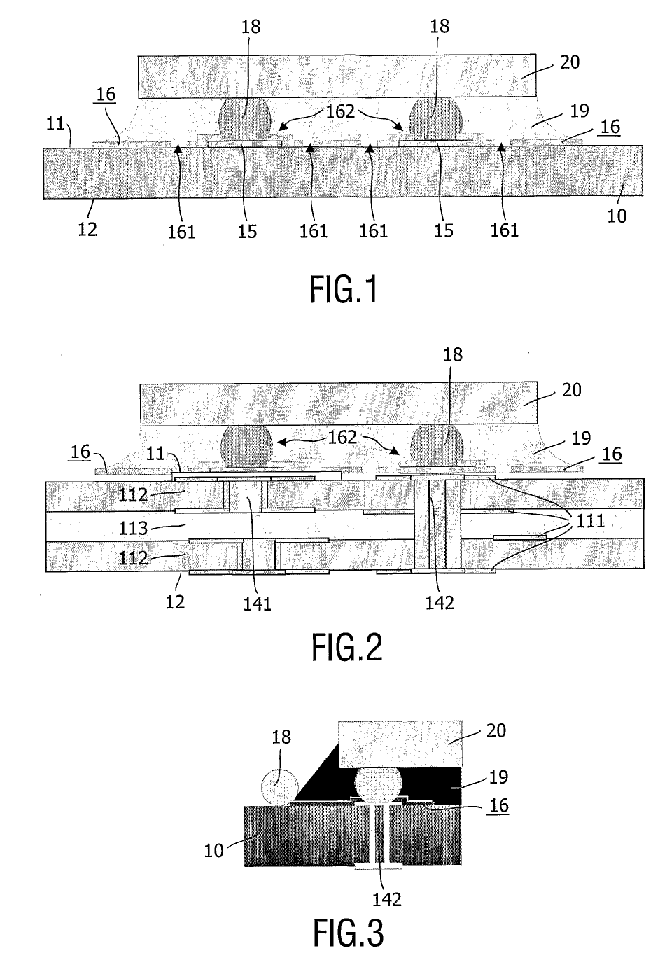

FIG. 1 diagrammatically shows a cross-sectional view of a first embodiment of the assembly;

FIG. 2 diagrammatically shows a cross-sectional view of a second embodiment of the assembly; and

FIG. 3 shows diagrammatically a cross-sectional view of a detail in a prior art assembly.

The Figures are not drawn to scale and like reference numbers in different figures refer to like parts.

FIG. 1 shows diagrammatically a cross-sectional view of the assembly according to the invention. The assembly comprises a carrier substrate 10 and an electronic device 20, in this case a semiconductor chip such as a power amplifier. The carrier substrate 10 has a first side 11 and an opposite second side 12. Bond pads 15 are present on the first side 11 of the carrier substrate. Generally, the bond pads 15 are defined in an upper metal layer of the substrate 10, and are provided with an adhesive layer. The metal layer contains for instance copper, or aluminum, and the adhesive layer contains for instance gold, or an alloy of palladium and gold, or otherwise. In order to provide sufficient strength, it is suitable to use an underbump metallization as part of the bond pads. This is known per se. A solder resist layer 16 is present on the first side 11 of the carrier substrate 10 as well. According to the invention, this solder resist layer 16 is provided in a specific pattern. This pattern includes an aperture 161 that is ring-shaped and forms the circumference of the bond pad 15. In a bond pad area 162 the solder resist layer covers the bond pad 15 partially, so as to define adequately the surface of the bond pad 15. Solder connections 18 are present between the bond pads 15 and corresponding pads at the electronic device 20. These connections provide a mechanical support for the electronic device 20 and an electrical connection. Basically, any space left between the carrier substrate 10 and the electronic device 20 is filled with an encapsulant 19, generally a material referred to as underfill.

FIG. 2 shows a second embodiment of the assembly of the invention in a diagrammatical cross-sectional view. The carrier substrate 10 of this embodiment is a laminate comprising four electrically conducting layers 111, which are mutually separated by core layers 112 of an epoxy material and a prepreg layer 113, as known in the art. Additionally, the carrier substrate 10 is provided with a vertical interconnect 141, that is positioned directly under the bond pad 15. This has the aim of providing an acceptable connection to the electrically conducting layer 11 that is used for grounding. Another vertical interconnect 142 is shown as a thermal via for heat dissipation. It extends from the first side 11 to the second side 12 of the carrier substrate 10.

In this embodiment, the bumps 18 used as the solder connection were attached to the electronic device 20 before the assembling of this device 20 and the carrier substrate 10. The solder bumps 18 were applied on an aluminum bump pad covered with a sputtered Al/NiV/Cu under bump metallization (UBM) 152 μm in diameter. The carrier substrate 10 has copper bond pads 15 with Ni/Au plating defined by Ø175 μm circular openings in the solder resist layer 16. A solder paste was provided on the bond pads 15 of the carrier substrate 10 before assembly. In this example, use was made of seven bumps 18. The electronic device 20 is in this example a passive network that is in use for impedance matching.

It has been found that the vias 142 play an important role in the stress around the bumps on a thermal via. Also important is the loss of stiffness of the solder due to the melting in the reflow step. The stress will abruptly shift to tensile stress around the bumps 16 on a via when the solder is de-activated. When no vias are present, the stresses will be compressive above ≈200° C. At room temperature however, the interface stresses are compressive near bumps 16 on a via 141, 142 and tensile for bumps 16 without via 141, 142. Apparently the higher tensile stress at room temperature is less critical than the low stress above 200° C. A lower interface strength at high temperature is indeed very likely. Shear measurements, performed on non-reflowed but underfilled dies, did show a 4× higher strength at room temperature than at 220° C. This observation complies with the experimental observation where delamination was found to occur between 210° C. and 230° C. around bumps 16 with vias 141, 142 only, but without any aperture 161 in the solder resist layer 16. It is to be mentioned that the interfacial stresses—and therewith the chance of delamination—in situations without apertures 161 in the solder resist layer 16 tend to increase in view of slight misalignment of a bump with respect to a via, or in the situation of a via without a bump. The final problem with the delamination is the fact that molten solder will flow out of its required place to a position adjacent to the underfill. This failure mechanism is shown in detail in FIG. 3.

Several other devices are placed on the same carrier substrate 10 in addition to the electronic device 20. These devices include both discrete passive components and semiconductor devices such as amplifiers. Use is made of various techniques for the electrical connection, including wirebonding. Additionally, a protecting cap is provided on the carrier substrate 10 (not shown).

The assembly process comprises several steps, in order to combine the wirebonding and other assembly steps, such as the assembly with bumps (also known as flip-chip). In the first step a prebake of the carrier substrate 10 is carried out. This results in an improved heat stability of the carrier substrate 10.

In step II, solder paste, for instance a SnAg3.8Cu0.7 solder paste with any conventional additions, is printed on the bond pads 15 of the carrier substrate 10. In step III, electronic devices are assembled on the first side 11 of the carrier substrate 10, and solder connections are provided to the bond pads 15, as provided with solder paste in the previous step. The assembly of electronic devices includes electronic devices that are assembled with bumps, such as the electronic device 20, and electronic devices that are assembled with SMD-contacts. The latter group of electronic devices includes for instance discrete passive components and also discrete active components.

In step IV, the assembly is put into an oven for reflow soldering. Herein, the devices with SMD contacts and those with bumps are electrically connected properly. In step V, the solder paste that has not been used or not been integrated into a proper connection is taken away in a conventional cleaning step.

Only in step VI are the further components provided on the laminate. These are the components that are to be electrically connected by wirebonding. These further components are attached to the carrier substrate with a proper thermally or electrically conducting adhesive, that is subsequently cured. After a plasma clean in step VII, wirebonding are made in step VIII in a manner known to a skilled person.

In step IX, an underfill 19 is disposed so as to fill any space between the electronic device 20 and the carrier substrate 10, in case bumps are used as the solder connection 16. The underfill 19 may further be applied atop the wirebondings, so as to provide an additional protection. The dispense of the underfill 19 is followed by a step in which it is cured.

Finally, a cap is provided and glued to the carrier substrate 10, and the carrier substrate 10 is subdivided into individual products.

1. An assembly comprising an electronic device that is attached to a first side of a carrier substrate with solder connections, said first side of the substrate being provided with bond pads and a solder resist layer, any space between the substrate and the electronic device being filled with an encapsulant, the substrate further comprising contact pads for connection to an external board, characterized in that the solder resist layer is patterned according to a pattern that includes an aperture adjacent to a first bond pad, which aperture is ring-shaped and forms the circumference of the first bond pad.

2. An assembly as claimed in claim 1, wherein the first bond pad is located on top of a vertical interconnect extending into the carrier substrate.

3. An assembly as claimed in claim 3, wherein the carrier substrate comprises electrically insulating material and internal conductors.

4. An assembly as claimed in claim 1, further comprising a second electronic device that is attached to the first side of the carrier substrate, the first and second electronic devices being mutually interconnected via interconnects on and/or in the carrier substrate.

5. An assembly as claimed in claim 1, wherein:
a second bond pad neighboring the first bond pad is present,
the solder resist layer comprising a second aperture that is ring-shaped and forms the circumference of the second bond pad, which second aperture fuses with the first aperture in an area between the first and the second bond pad.

6. A method of placing an assembly onto an external board with a reflow soldering process, wherein the assembly according to any of the claim 1.
